(19) United States
(12) Patent Application Publication
(10) Pub. No.: US 2025/0190655 A1
(43) Pub. Date: Jun. 12, 2025

(54) METHOD AND DEVICE FOR SIMULATING PERFORMANCE OF SEMICONDUCTOR DEVICE, AND SYSTEM AND METHOD FOR EVALUATING PERFORMANCE OF SEMICONDUCTOR DEVICE

(71) Applicant: SAMSUNG ELECTRONICS CO., LTD., Suwon-si (KR)

(72) Inventors: Sungmin Hong, Gwangju-si (KR); Philhun Ahn, Gwangju-si (KR)

(73) Assignee: Gwangju Institute of Science and Technology, Gwangju (KR)

(21) Appl. No.: 18/968,499

(22) Filed: Dec. 4, 2024

(30) Foreign Application Priority Data
Dec. 7, 2023 (KR) 10-2023-0176805
Jul. 11, 2024 (KR) 10-2024-0092015

(51) Int. Cl. G06F 30/25; G06F 30/367

(52) U.S. Cl. CPC G06F 30/25; G06F 30/367

(57) ABSTRACT

A method implemented on a computer and for simulating performance of a semiconductor device model includes, for the semiconductor device model, establishing a carrier distribution function that represents the distribution of carriers, obtaining a scattering term based on geometric scattering of the carriers, for the carrier distribution function, calculating a solution of the multi-subband Boltzmann transport equation (MSBTE) that includes the scattering term, and outputting a performance value of the semiconductor device model corresponding to the solution of the MSBTE. Geometric scattering of the carriers is scattering in a region where a shape of a cross-section of the semiconductor device taken in a direction perpendicular to a first direction changes.

### CROSS-REFERENCE TO RELATED APPLICATIONS

This application claims priority to Korean Patent Application Nos. 10-2023-0176805, filed on Dec. 7, 2023, and 10-2024-0092015, filed on Jul. 11, 2024, in the Korean Intellectual Property Office, the disclosures of which are incorporated by reference herein in their entireties.

### BACKGROUND

Semiconductor device simulation predicts the performance of semiconductor devices using computer programs. In order to reduce time and cost in the process of developing a semiconductor device, semiconductor device simulation may be performed.

In semiconductor device simulation, the performance of semiconductor devices may be predicted through the movement of electrons/holes (i.e., carriers) inside the semiconductor device, and various simulation methods may exist depending on the level at which the movement of the carriers may be handled.

### SUMMARY

In general, in some aspects, the present disclosure is directed toward a method, device, and system capable of stably and efficiently performing numerical analysis on a semiconductor device having a non-uniform cross-section.

According to some implementations, the present disclosure is directed to a method that is implemented on a computer and simulates the performance of a semiconductor device model corresponding to a semiconductor device, the method including for the semiconductor device model, establishing a carrier distribution function that represents the distribution of carriers having states having a specific energy at a specific position in real space, obtaining a scattering term based on geometric scattering of the carriers, for the carrier distribution function, calculating a solution of the multi-subband Boltzmann transport equation (MSBTE) including the scattering term, and outputting a performance value of the semiconductor device model corresponding to the solution of the multi-subband Boltzmann transport equation including the scattering term as a result value of the simulation, wherein the geometric scattering of the carriers is scattering in a region where the shape of a cross-section formed by taking the semiconductor device in a direction perpendicular to a first direction changes in the first direction.

According to some implementations, the present disclosure is directed to a device including a memory configured to store code data representing a multi-subband Boltzmann transport equation including a scattering term and characteristics data representing characteristics of semiconductor device models corresponding to semiconductor devices, and a processor configured to simulate the performance of the semiconductor device model based on the code data and the characteristics data, and output the performance value of the semiconductor device model as the result value of the simulation, wherein the processor is configured to, for the semiconductor device model, establish a carrier distribution function that represents the distribution of carriers having states having a specific energy at a specific position in real space, for the carrier distribution function, calculate a solution of the multi-subband Boltzmann transport equation including the scattering term, and process the performance value of the semiconductor device model based on the solution of the multi-subband Boltzmann transport equation including the scattering term, wherein the scattering term is determined based on the geometric scattering of carriers in a region where the shape of the cross-section of the semiconductor device changes.

According to some implementations, the present disclosure is directed to a system including a semiconductor device, a measurement device configured to measure the characteristics of the semiconductor device, and a simulation device configured to simulate the performance of a semiconductor device model corresponding to the semiconductor device, wherein the simulation device calculates a solution of the multi-subband Boltzmann transport equation including a scattering term based on code data representing a multi-subband Boltzmann transport equation with scattering terms and characteristics data representing the characteristics relating to the semiconductor device model, to thereby generate a performance value of the semiconductor device model corresponding to the solution of the multi-subband Boltzmann transport equation including the scattering term as a result value of the simulation, and output an evaluation value obtained by evaluating the performance of the semiconductor device, based on the result value of the simulation and a measurement value provided by the measurement device, wherein the scattering term is determined based on the geometric scattering of carriers in a region where the shape of the cross-section obtained by taking the semiconductor device in a direction perpendicular to a first direction changes in the first direction.

According some implementations, the present disclosure is directed to a method that is implemented on a computer and simulates the performance of a semiconductor device, the method including receiving characteristics information representing a characteristics value of the semiconductor device, simulating the performance of a semiconductor device model constructed according to the characteristics information based on the Boltzmann transport equation including a scattering term, receiving measurement information representing a measurement value obtained by measuring characteristics of the semiconductor device, outputting evaluation information evaluating the performance of the semiconductor device based on the simulation result value and the measurement value, wherein the scattering term is determined based on the geometric scattering of carriers in a region where the shape of the cross-section obtained by taking the semiconductor device in a direction perpendicular to a first direction changes in the first direction.

According to some implementations, the present disclosure is directed to a computer program stored in a computer-readable recording medium for implementing a method that simulates the performance of a semiconductor device.

### BRIEF DESCRIPTION OF THE DRAWINGS

Example implementations will be more clearly understood from the following detailed description, taken in conjunction with the accompanying drawings.

FIG. 1 is a block diagram illustrating an example of a performance evaluation system according to some implementations.

FIG. 2 is a block diagram illustrating an example of a simulation device according to some implementations

FIGS. 3A and 3B are diagrams showing an example of a semiconductor device that may be a simulation target according to some implementations.

FIG. 4 is a graph showing an example of geometric scattering of carriers according to a shape change of a cross-section in a semiconductor device having the structure of FIG. 3B according to some implementations.

FIG. 5 is a flowchart illustrating an example of a method of evaluating performance according to some implementations.

FIG. 6 is a flowchart illustrating an example of a simulation method according to some implementations.

FIG. 7 is a flowchart illustrating an example of a method of establishing a multi-subband Boltzmann transport equation including a scattering term according to some implementations.

FIG. 8 is a graph illustrating an example of a current component according to a position of a channel in the longitudinal direction in a semiconductor device having the structure of FIG. 3B that appears in a simulation method according to some implementations.

### DETAILED DESCRIPTION

Hereinafter, example implementations will be explained in detail with reference to the accompanying drawings.

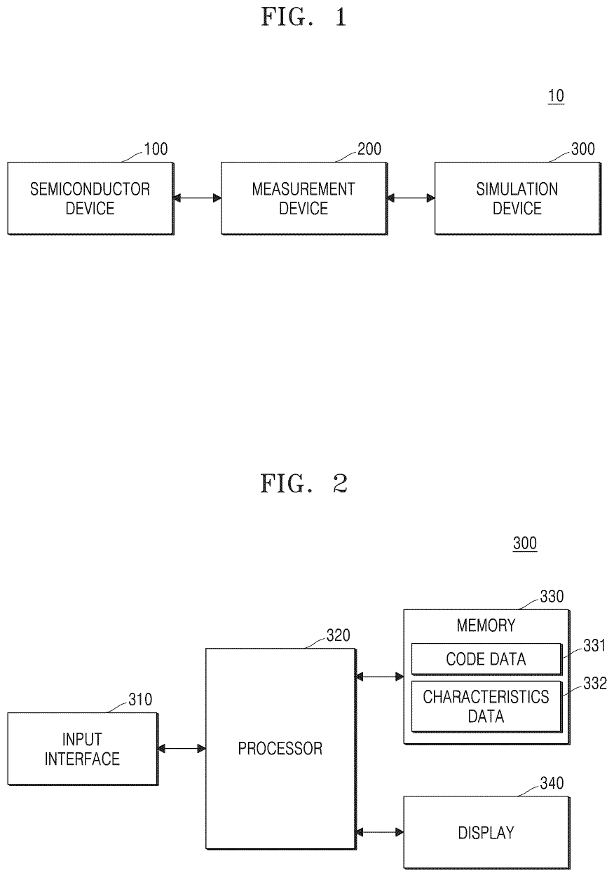

FIG. 1 is a block diagram illustrating an example of a performance evaluation system according to some implementations. In FIG. 1, a performance evaluation system 10 may be a system for testing the performance of a newly developed semiconductor device 100. The performance evaluation system 10 may include a semiconductor device 100, a measurement device 200, and a simulation device 300.

The semiconductor device 100 may be a device developed by a designer. The semiconductor device 100 may have various characteristics. Here, the characteristics of the semiconductor device 100 may include physical characteristics, electrical characteristics, and the like. Physical characteristics may include, for example, a magnitude such as a width, thickness, length, and area of the semiconductor device 100, a length of a channel included in the semiconductor device 100, a material included in the semiconductor device 100, and the like. Electrical characteristics may include, for example, direct-current (DC) current, transient response characteristics, threshold voltage, carrier speed, carrier density, and the like.

The measurement device 200 may measure characteristics of the semiconductor device 100. In some implementations, the measurement device 200 may measure physical characteristics of the semiconductor device 100. In some implementations, the measurement device 200 may apply a supply voltage to the semiconductor device 100, and the measurement device 200 may measure the electrical characteristics of the semiconductor device 100 while the supply voltage is applied to the semiconductor device 100. The measurement device 200 may provide the simulation device 300 with a measured value obtained by measuring the characteristics of the semiconductor device 100.

The simulation device 300 includes all various devices capable of providing a result to a user by performing an operation process. For example, the simulation device 300 may include both a computer and a portable terminal, or may be in any one form.

The computer may include, for example, a laptop, a desktop, a laptop, a tablet personal computer (PC), a slate PC, and the like, which is equipped with a web browser. For example, portable terminals are wireless communication devices that guarantee portability and mobility, including all kinds of handheld-based wireless communication devices such as Personal Communication System (PCS) terminals, Global System for Mobile Communications (GSM) terminals, Personal Digital Cellular (PDC) terminals, Personal Handy-phone System (PHS) terminals, Personal Digital Assistant (PDA) terminals, International Mobile Telecommunication (IMT)-2000 terminals, Code Division Multiple Access (CDMA)-2000 terminals, W-CDMA terminals, Wireless Broadband Internet (WiBro) terminals, smartphones, etc. and wearable devices such as watches, rings, bracelets, glasses, or head-mounted-devices (HMDs).

The simulation device 300 may simulate the performance of a semiconductor device model corresponding to the semiconductor device 100. A computer semiconductor device model is a model reflecting the characteristics of the semiconductor device 100, and may be implemented on a computer. For example, when a user, designer, etc. inputs the characteristics value of a semiconductor device 100 to a computer, a semiconductor device model may be implemented in a computer (or a program stored in a computer) by a program (or various applications) stored in the computer. The simulation device 300 may store characteristics data indicating characteristics of the semiconductor device model.

The simulation device 300 may establish a carrier distribution function for the semiconductor device model based on the characteristics data. The carrier distribution function may be a function representing a distribution of carriers each having a state having a specific energy at a specific position in a real space. The carriers may be electrons and/or holes.

The simulation device 300 may calculate a solution of a multi-subband Boltzmann transport equation including a scattering term for the carrier distribution function based on code data representing the multi-subband Boltzmann transport equation (MSBTE) including the scattering term and characteristics data representing the characteristics of the semiconductor device model.

The scattering term may be obtained based on geometric scattering of carriers. Here, the geometric scattering may be scattering occurring in a region in which a cross-section of a semiconductor device to be simulated is uneven. That is, the scattering term may be determined based on geometric scattering of carriers in a region in which the shape of a cross-section of the semiconductor device changes. For example, the scattering term may be determined based on the geometric scattering of carriers in a region where the shape of the cross-section obtained by taking the semiconductor device in a direction perpendicular to a first direction changes in the first direction. The first direction may be the longitudinal direction of a channel included in the semiconductor device.

For example, at least one of the cross-sections of the source region and the drain region of the semiconductor device may have a shape different from the shape of the cross-section of the channel region thereof. In this case, the scattering term may be determined based on geometric scattering occurring in a region where at least one of the source region and the drain region meets the channel region.

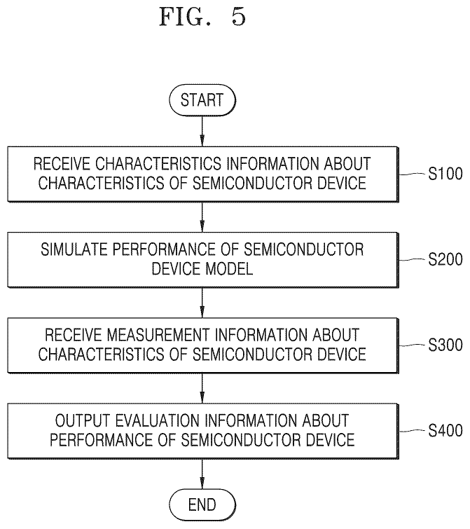

As in various implementations, when a multi-subband Boltzmann transport equation including a scattering term based on geometric scattering is applied to the simulation operation of the simulation device 300, the simulation device 300 may efficiently simulate the performance of the semiconductor device model based on the multi-subband Boltzmann transport equation, even for a semiconductor device having a non-uniform cross-section. A specific description of the multi-subband Boltzmann transport equation including scattering terms based on geometric scattering is described with reference to FIGS. 5 to 7.

Simulations using the general multi-subband Boltzmann transport equation divide the state of electrons and holes in a channel of a semiconductor device into several groups called subbands, considering a quantum mechanical binding effect inside the semiconductor device, and the movement of electrons and holes in a specific subband is interpreted by solving the Boltzmann transport equation, which is a classic transport equation. In this way, simulations using the multi-subband Boltzmann transport equation, which considers multiple subbands and solves the Boltzmann transport equation, may allow efficient simulations to be performed by treating each subband as a separate group that does not interact with each other.

However, when the shape of the cross-section of a semiconductor device is not uniform, electrons and holes may belong to a different subband rather than the initial subband as the electrons and holes move along the channel. Accordingly, the general multi-subband Boltzmann transport equation has difficulty in simulating semiconductor devices with non-uniform cross-sections.

Various implementations according to the present disclosure may accurately simulate a semiconductor device with a non-uniform cross-section by adding a scattering term considering geometric scattering caused by the non-uniform cross-section to the multi-subband Boltzmann transport equation.

Specifically, in various implementations, the interaction between different subbands is treated as if there is no interaction (the similarity between different subbands is treated as 0) like a simulation using a general multi-subband Boltzmann transport equation, but by analyzing the multi-subband Boltzmann transport equation with an added scattering term considering geometric scattering, it is possible to stably and efficiently simulate a semiconductor device having an uneven cross-section.

The simulation device 300 may calculate a solution of a multi-subband Boltzmann transport equation including a scattering term, thereby calculating a performance value of a semiconductor device model corresponding to the solution. The performance value of the semiconductor device model may correspond to the characteristics value of the semiconductor device 100.

The simulation device 300 may generate and/or output a performance value of the semiconductor device model as a result value of the simulation. In addition, the simulation device 300 may output an evaluation value evaluating the performance of the semiconductor device based on the result value of the simulation and the measurement value provided from the measurement device 200.

As described above, the performance evaluation system 10 may accurately evaluate the performance of a semiconductor device model with an uneven cross-sectional shape by using a multi-subband Boltzmann transport equation including a scattering term.

FIG. 2 is a block diagram illustrating an example of a simulation device according to some implementations. In FIG. 2, the simulation device 300 may include an input interface 310, a processor 320, a memory 330, and a display 340.

The input interface 310 may serve as a passage with various types of external devices connected to the simulation device 300. In some implementations, the input interface 310 may receive input information including an input value from a user or the like. The input information may include, for example, a characteristics value of the semiconductor device 100.

The input interface 310 may communicate with the processor 320. In some embodiments, the input interface 310 may provide input information received from the outside to the processor 320.

The input interface 310 may include at least one of a wired/wireless headset port, an external charger port, a wired/wireless data port, a memory card port, a port for connecting a device including a subscriber identification module (SIM), an audio input/output (I/O) port, a video I/O port, and an earphones port.

The processor 320 may process various functions performed in the simulation device 300 or control functions. The processor 320 may control the operation of the input interface 310, the operation of the memory 330, and/or the operation of the display 340.

The processor 320 may control at least some of the components shown in FIG. 2 in order to drive an application program stored in the memory 330. Furthermore, the processor 320 may operate by combining at least two or more of components included in the simulation device 300 with each other to drive the application program.

In addition to the operation related to the application program, the processor 320 may generally control the overall operation of the simulation device 300. The processor 320 may provide or process appropriate information or functions to the user by processing signals, data, information, and the like input or output through the components described above or by driving the application program stored in the memory 330.

The processor 320 may load code data 331 and characteristics data 332 from the memory 330. The processor 320 may simulate the performance of the semiconductor device model based on the code data 331 and the characteristics data 332, and output the performance value of the semiconductor device model as a result value of the simulation. The processor 320 may establish a semiconductor device model using the characteristics data 332. In addition, the processor 320 may establish a carrier distribution function of the semiconductor device model with respect to the total energy. The processor 320 may obtain a multi-subband Boltzmann transport equation including a scattering term from the code data 331. The processor 320 may calculate a solution of a Boltzmann transport equation including a scattering term with respect to the carrier distribution function. A specific description of the multi-subband Boltzmann transport equation including scattering terms is described with reference to FIGS. 5 to 7.

The processor 320 may process the performance value of the semiconductor device model based on the solution of the multi-subband Boltzmann transport equation including the scattering term.

The memory 330 may store data supporting various functions of the simulation device 300. The memory 330 may store a plurality of application programs or applications driven in the simulation device 300, and data and instructions for the operation of the simulation device 300. The memory 330 may be implemented as a memory device.

The memory 330 may store code data 331 and characteristics data 332. The code data 331 may be data representing code for implementing a multi-subband Boltzmann transport equation including a scattering term. The characteristics data 332 may be data representing characteristics of a semiconductor device model.

In some implementations, the simulation apparatus 300 may further include a communication module configured to perform wired/wireless communication with an external apparatus. Wireless communications may include, for example, Wireless LAN (WLAN), Wireless-Fidelity (Wi-Fi), Wi-Fi Direct, Digital Living Network Alliance (DLNA), WiBro, and World Interoperability for Microwave Access (WiMAX), High Speed Downlink Packet Access (HSDPA), High Speed Uplink Packet Access (HSUPA), Long Term Evolution (LTE), Long Term Evolution-Advanced (LTE-A), etc. Short range communication technologies may include, for example, Bluetooth™, Radio Frequency Identification (RFID), Infrared Data Association (IrDA), Ultra WideBand (UWB), ZigBee, Near Field Communication (NFC), Wi-Fi, Wi-Fi Direct, Wireless Universal Serial Bus (Wireless USB), etc.

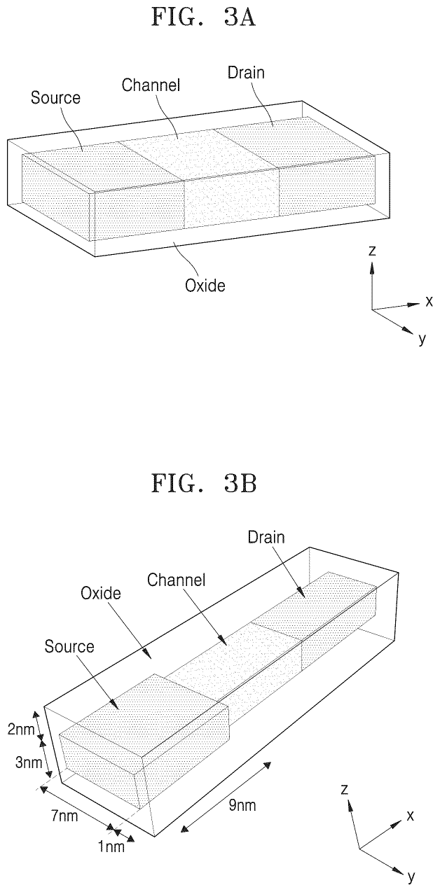

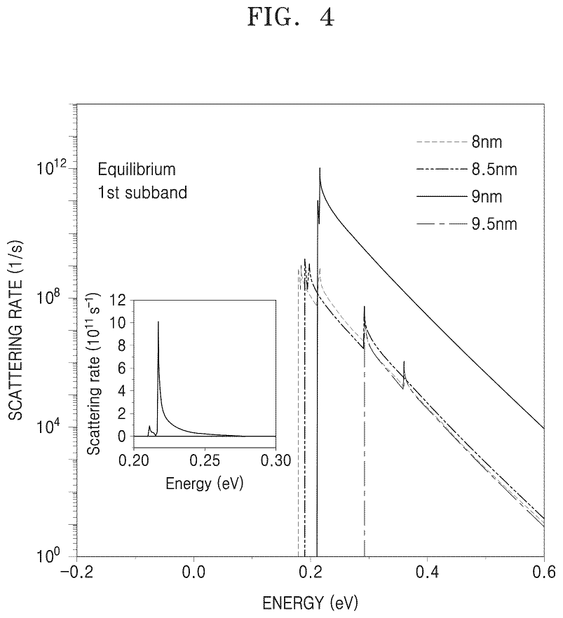

FIGS. 3A and 3B are diagrams showing an example of a semiconductor device that may be a simulation target according to some implementations. FIG. 4 is a graph showing an example of geometric scattering according to a shape change of a cross-section in a semiconductor device having the structure of FIG. 3B according to some implementations. Referring to FIGS. 3A and 3B, FIG. 4 illustrates a scattering rate per unit time in a semiconductor device having the structure of FIG. 3B according to energy. The semiconductor device may include a source region, a drain region, a channel region, and an oxide layer.

FIG. 3A illustrates a semiconductor device having a uniform cross-section, and FIG. 3B illustrates a semiconductor device having a non-uniform cross-section. In the present disclosure, a uniform cross-section may mean that the shape of a cross-section of a semiconductor element cut in a direction perpendicular to a first direction (x direction) is constant in the first direction (x direction), and a non-uniform cross-section may mean that the shape of a cross-section of a semiconductor element cut in a direction perpendicular to the first direction (x direction) is not constant in the first direction (x direction). In FIGS. 3A and 3B, the first direction (x-direction) may be the longitudinal direction of a channel included in a semiconductor device.

In FIGS. 3A and 3B, the uniform cross-section may mean that the shape of the cross-section of the yz plane is constant, and the non-uniform cross-section may mean that the shape of the cross-section of the yz plane is not constant. It may be seen from FIG. 3A that the shape of the yz plane in the x direction is constant, and it may be seen from FIG. 3B that the shape of the yz plane in the x direction is changed at a region (9 nm point) where the source region and the channel region meet.

In FIG. 4, it may be seen that the movement of electrons due to geometric scattering is the most active at a 9 nm point, which is a region in which the shape of the cross-section of the semiconductor device shown in FIG. 3B is changed, and the influence of geometric scattering is not significant in other regions (8 nm, 8.5 nm, and 9.5 nm).

As described above with reference to FIG. 1, the simulation using the general multi-subband Boltzmann transport equation may only be applied to semiconductor devices with a uniform cross-section as shown in FIG. 3A, and it is difficult to apply the general multi-subband Boltzmann transport equation to semiconductor devices with a non-uniform cross-section as shown in FIG. 3B. The simulation method according to some implementations may be applied to a semiconductor device having a non-uniform cross-section, as shown in FIG. 3B, by using a multi-subband Boltzmann transport equation including a scattering term based on geometric scattering.

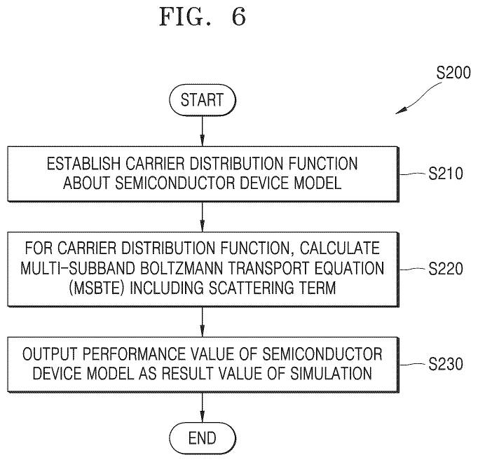

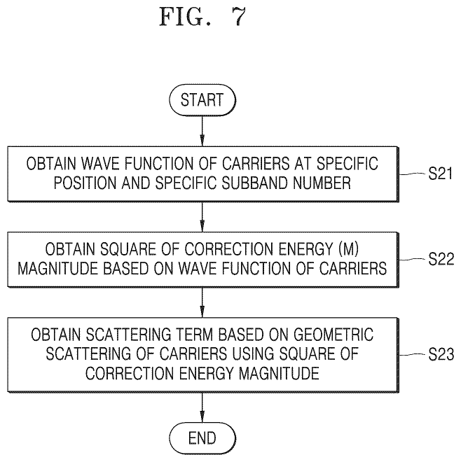

FIG. 5 is a flowchart illustrating an example of a method of evaluating performance according to some implementations. FIG. 6 is a flowchart illustrating an example of a simulation method according to some implementations. FIG. 7 is a flowchart illustrating an example of a method of establishing a multi-subband Boltzmann transport equation including a scattering term according to some implementations.

In FIG. 5, the performance evaluation method may be implemented on a computer. In some implementations, the performance evaluation method illustrated in FIG. 5 may be performed by the performance evaluation system 10 illustrated in FIG. 1.

In FIG. 5, an operation of receiving characteristics information about the characteristics of the semiconductor device is performed (S100). Here, the characteristics information may include, for example, a characteristics value of a semiconductor device. The characteristics information may be input by, for example, a user, a designer, or the like. Referring back to FIG. 1, for example, the simulation device 300 may receive characteristics information about characteristics of the semiconductor device 100.

In FIG. 6, an operation of simulating the performance of the semiconductor device model is performed (S200). The semiconductor device model may be implemented on a computer according to the characteristics information received in operation S100. A specific description of operation S200 is made below with reference to FIG. 6.

An operation of receiving measurement information about the characteristics of the semiconductor device is performed (S300). Measurement information on the characteristics of the semiconductor device may include a measured value on which the characteristics of the semiconductor device are measured. The measurement information may be generated by the measurement device 200 illustrated in FIG. 1. Referring back to FIG. 1, for example, the measurement device 200 may measure the characteristics of the semiconductor device 100 and provide measurement information to the simulation device 300. The simulation device 300 may receive measurement information.

An operation of outputting evaluation information on the performance of the semiconductor device is performed (S400). Specifically, the operation of outputting evaluation information evaluating the performance of the semiconductor device based on the simulation result value and the measured value is performed (S400). Referring back to FIG. 1, for example, the simulation device 300 may evaluate the performance of the semiconductor device 100 by determining the degree of similarity between the simulation result value and the measured value. Referring back to FIG. 1, as another example, the simulation device 300 may evaluate the performance of the semiconductor device 100 by determining whether the simulation result value matches the measured value.

In addition, the performance evaluation method shown in FIG. 5 may be implemented as a computer program stored in a computer-readable recording medium combined with a computer, which is hardware.

As described above, the performance evaluation method may efficiently and accurately evaluate the performance of the semiconductor device model, even in the case of a semiconductor device with a non-uniform cross-section.

FIG. 6 is a flowchart illustrating an example of a simulation method according to some implementations. In FIG. 6, the simulation method illustrated in FIG. 6 may correspond to operation S200 illustrated in FIG. 5.

An operation of establishing a carrier distribution function for the semiconductor device model is performed (S210). The carrier distribution function may be a function representing a distribution of carriers each having a state having a specific energy at a specific position in a real space.

For the carrier distribution function, an operation of calculating a solution of a multi-subband Boltzmann transport equation (MSBTE) including a scattering term is performed (S220). The scattering term may be determined based on geometric scattering of carriers. The multi-subband Boltzmann transport equation including a scattering term may be derived by considering a Hamiltonian operator that keeps the electron concentration equally.

Considering a Hamiltonian operator that keeps the electron concentration equally means that simulating a semiconductor device model with a non-uniform cross-section is equivalent to simulating by changing the Hamiltonian operator in a semiconductor device model with a uniform cross-section. For example, simulation results of a semiconductor device model with a non-uniform cross-section with a Hamiltonian operator that is H may be the same as those of a semiconductor device model with a uniform cross-section with a Hamiltonian operator that is H+Σ_{scat,H}^{r}+Σ_{scat,AH}^{r}. In other words, the scattering term based on geometric scattering may be derived under the condition that the electron concentration by the changed Hamiltonian operator H+Σ_{scat,H}^{r}+Σ_{scat,AH}^{r} is the same as the electron concentration by the original Hamiltonian operator H. Here, H+Σ_{scat,H}^{r} is a Hermitian matrix for the energy of the real number, and Σ_{scat,AH}^{r} is an anti-Hermitian matrix for the energy of the imaginary number, which is related to the transition of electrons and holes to other states without staying in certain states, and this may be understood as geometric scattering in this specification.

Unlike the assumptions of the typical multi-subband Boltzmann transport equation, in reality, electrons and holes may transition from one subband to another as the electrons and holes move in the longitudinal direction of a channel. H+Σ_{scat,H}^{r} is a term indicating that electrons and holes move in the existing subband as they are without transferring to other subbands in the process of moving. Σ_{scat,AH}^{r} is a term indicating that electrons and holes are transferred to other subbands in the process of moving, and the physical state changed by Σ_{scat,H}^{r} may be corrected.

In FIG. 7, a method of establishing a multi-subband Boltzmann transport equation including a scattering term, according to embodiments, may first obtain a wave function of carriers at a specific position and a specific subband number (S21), and obtain the square of the magnitude of the correction energy (M) based on the wave function of the carriers (S22), based on Equation 1 below.

$${\vert M \vert}^{2} = \vert < {ψ}_{i , j} {\vert {ψ}_{k , l} > \frac{{ℏ}^{2}}{2 {{m}_{x} ( Δ x )}^{2}} \vert}^{2} \qquad ( Equation 1 )$$

where i and k are indexes of the specific position, j and l are indexes of the subband number, ψ_{i,j} and ψ_{k,l} are the wave functions, mₓ is the mass of the carrier in the first direction, Δx is the distance between xᵢ and xₖ, ℏ is the reduced Planck constant, and |M| is the correction energy magnitude.

In some implementations, the magnitude of the correction energy may be the magnitude of the energy calculated by H+Σ_{scat,H}^{r} described above. In some implementations, the correction energy magnitude may be determined based on a similarity being 0 between subbands of different numbers among subbands. In some implementations, the correction energy magnitude may be determined by assuming that the shape of the cross-section cut in a direction perpendicular to a first direction (x direction) is constant in the first direction (x direction).

A scattering term based on geometric scattering of carriers may be obtained by using the square of the correction energy magnitude (S23). The scattering term may be calculated as in Equation 2 below.

$$\frac{1}{{τ}_{geo , out}} ( {x}_{i} , m , E ) = \frac{2 π}{ℏ} {\vert M \vert}^{2} Z ( {x}_{i + 1} , n , E ) [ 1 - f ( {x}_{i + 1} , n , E ) ] Δ x \qquad ( Equation 2 )$$

where xᵢ and xᵢ₊₁ are specific positions, m and n are subband numbers,

$$\frac{1}{{τ}_{geo , out}}$$

is a scattering term, ℏ is the reduced Planck constant, E is the specific energy, Z is the density-of-states, f is a carrier distribution function, Δx is the distance between xᵢ and xᵢ₊₁, and |M|² is the square of a correction energy magnitude.

In some implementations, the scattering term may be determined based on a ratio at which a carrier belonging to the first subband is transferred to a second subband of a number different from the first subband when moving in the first direction (x direction).

The multi-subband Boltzmann transport equation including the scattering term is shown in Equation 3 below, and may be completed by substituting the scattering term obtained through Equation 2.

$$v ( {x}_{i + 0.5} , m ) Z ( {x}_{i + 0.5} , m ) f ( {x}_{i + 0.5} , m ) - v ( {x}_{i - 0.5} , m ) Z ( {x}_{i - 0.5} , m ) f ( {x}_{i - 0.5} , m ) - \frac{1}{{τ}_{geo , out}} Z ( {x}_{i} , m ) f ( {x}_{i} , m ) Δ x \qquad ( Equation 3 )$$

where ν is the speed of a carrier in the first direction (x direction), x_{i+0.5} and x_{i-0.5} are the specific positions, m is the subband number, E is specific energy, Z is the state density, f is a carrier distribution function, Δx is the distance between x_{i+0.5} and x_{i-0.5}, and

$$\frac{1}{{τ}_{geo , out}}$$

is a scattering term.

Referring back to FIG. 6, for the carrier distribution function, a solution of the multi-subband Boltzmann transport equation (MSBTE) including the scattering term described above is calculated (S220), and the performance value of the semiconductor device model is output as a simulation result value (S230). Specifically, an operation of outputting a performance value of the semiconductor device model corresponding to the solution of the multi-subband Boltzmann transport equation including the scattering term as a result value of the simulation, is performed (S230).

In addition, the simulation method shown in FIG. 6 may be implemented as a computer program stored in a computer-readable recording medium combined with a computer, which is hardware.

As described above, the simulation method may efficiently and accurately evaluate the performance of the semiconductor device model, even in the case of a semiconductor device with a non-uniform cross-section.

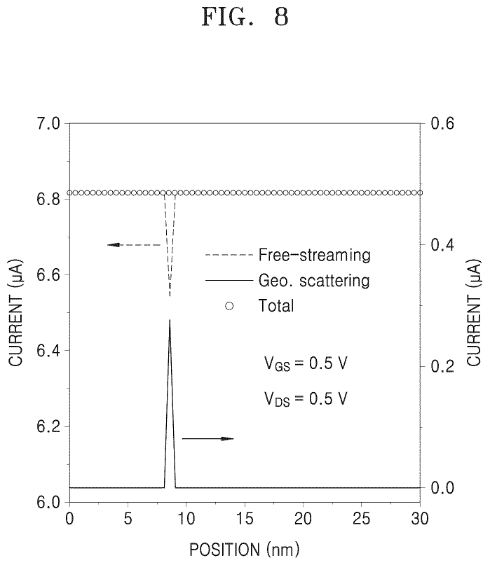

FIG. 8 is a graph illustrating an example of a current component according to a position of a channel in the longitudinal direction (x direction) in a semiconductor device having the structure of FIG. 3B that appears in a simulation method according to some implementations. In FIG. 8, Free-streaming is a current component based on the transfer of electrons and holes to existing subbands without transferring to other subbands while moving along the channel, and Geo.scattering is a current component based on the transfer of electrons and holes to other subbands while moving along the channel.

In FIG. 8, it may be seen that the total current component, which is the addition of the current component of Free-streaming and the current component of Geo.scattering, is constantly preserved even when the position of the channel changes in the longitudinal direction of the channel (specifically, at the point of 9 nm where the shape of the cross-section of the semiconductor device changes).

The method and device for simulating the performance of a semiconductor device, and a system and method for evaluating the performance of a semiconductor device, according to some implementations, may be performed using a multi-subband Boltzmann transport equation including a scattering term based on geometric scattering. The multi-subband Boltzmann transport equation including the scattering term is expressed as Equation 3 above. Accordingly, methods and devices for simulating the performance of semiconductor devices, and systems and methods for evaluating the performance of semiconductor devices, according to some implementations, may provide efficient and accurate numerical analysis for semiconductor device models with uneven cross-sections.

In addition, the present disclosure may be implemented in the form of a recording medium storing instructions executable by a computer. The instructions may be stored in the form of program code, and when executed by a processor, a program module may be generated to perform the operations of some implementations. The recording medium may be implemented as a computer-readable recording medium.

Computer-readable recording media include all types of recording media in which instructions that may be deciphered by a computer are stored. For example, the computer-readable recording media may include Read Only Memory (ROM), Random Access Memory (RAM), magnetic tape, magnetic disks, flash memories, and optical data storage devices.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

1. A method implemented on a computer for simulating performance of a semiconductor device model corresponding to a semiconductor device, the method comprising:
for the semiconductor device model, establishing a carrier distribution function that represents a distribution of carriers having states, the states having a specific energy at a specific position in real space;
obtaining a scattering term based on geometric scattering of the carriers;
for the carrier distribution function, calculating a solution of a multi-subband Boltzmann transport equation (MSBTE) that includes the scattering term; and
outputting a performance value of the semiconductor device model corresponding to the solution of the MSBTE that includes the scattering term as a result value of the simulation,
wherein the geometric scattering of the carriers is scattering in a region where a shape of a cross-section of the semiconductor device taken in a direction perpendicular to a first direction changes in the first direction.

2. The method of claim 1, wherein the first direction is a longitudinal direction of a channel of the semiconductor device.

3. The method of claim 1, further comprising, prior to the obtaining of the scattering term, obtaining a wave function of the carrier at the specific position and a specific subband number.

4. The method of claim 3, further comprising calculating a square of a correction energy magnitude (Equation 1) based on the wave function of the carrier:
$${\vert M \vert}^{2} = \vert < {ψ}_{i , j} {\vert {ψ}_{k , l} > \frac{{ℏ}^{2}}{2 {{m}_{x} ( Δ x )}^{2}} \vert}^{2} \qquad ( Equation 1 )$$
where i and k are indexes of the specific position, j and l are indexes of the specific subband number, ψ_{i,j} and ψ_{k,l}, are the wave functions, mₓ is a mass of the carrier in the first direction, Δx is a distance between xᵢ and xₖ, ℏ is a reduced Planck constant, and |M| is a correction energy magnitude.

5. The method of claim 4, wherein the correction energy magnitude is determined based on the carrier not transitioning from a subband of one number to a subband of another number, when the carrier moves in the first direction.

6. The method of claim 4, wherein the correction energy magnitude is determined based on a similarity of zero between subbands of different numbers among the subbands.

7. The method of claim 4, wherein the correction energy magnitude is determined based upon the shape of the cross-section of the semiconductor device in the direction perpendicular to the first direction being constant in the first direction.

8. The method of claim 4, wherein the scattering term is calculated by:
$$\frac{1}{{τ}_{geo , out}} ( {x}_{i} , m , E ) = \frac{2 π}{ℏ} {\vert M \vert}^{2} Z ( {x}_{i + 1} , n , E ) [ 1 - f ( {x}_{i + 1} , n , E ) ] Δ x \qquad ( Equation 2 )$$
where xᵢ and xᵢ₊₁ are the specific positions, m and n are the subband numbers,
$$\frac{1}{{τ}_{geo , out}}$$
is a scattering term, ℏ is a reduced Planck constant, E is a specific energy, Z is a density-of-states, f is a carrier distribution function, Δx is a distance between xᵢ and xᵢ₊₁, and |M|² is a square of the correction energy magnitude.

9. The method of claim 8, wherein the multi-subband Boltzmann transport equation including the scattering term is:
$$v ( {x}_{i + 0.5} , m ) Z ( {x}_{i + 0.5} , m ) f ( {x}_{i + 0.5} , m ) - v ( {x}_{i - 0.5} , m ) Z ( {x}_{i - 0.5} , m ) f ( {x}_{i - 0.5} , m ) - \frac{1}{{τ}_{geo , out}} Z ( {x}_{i} , m ) f ( {x}_{i} , m ) Δ x \qquad ( Equation 3 )$$
where ν is a speed of the carrier in the first direction, x_{i+0.5} and x_{i-0.5} are the specific positions, m is the subband number, E is the specific energy, Z is the state density, f is the carrier distribution function, Δx is the distance between x_{i+0.5} and x_{i-0.5}, and
$$\frac{1}{{τ}_{geo , out}}$$
is the scattering term.

10. The method of claim 1, wherein the scattering term is determined based on a ratio in which a carrier belonging to a first subband among the carriers transitions to a second subband of a different number from the first subband number when the carrier moves in the first direction.

11. A device comprising:
a memory configured to store code data representing a multi-subband Boltzmann transport equation that includes a scattering term and characteristic data representing characteristics of semiconductor device models corresponding to semiconductor devices; and
a processor configured to simulate a performance of one of the semiconductor device models based on the code data and the characteristic data, and to output a performance value of the one of the semiconductor device models as a result value of a simulation,
wherein the processor is configured to:
for the one of the semiconductor device models, establish a carrier distribution function that represents a distribution of carriers having states, the states having a specific energy at a specific position in real space,
for the carrier distribution function, calculate a solution of the multi-subband Boltzmann transport equation, and
process the performance value of the one of the semiconductor device models based on a solution of the multi-subband Boltzmann transport equation,
wherein the scattering term is determined based on geometric scattering of carriers in a region where a shape of a cross-section of one of the semiconductor devices changes.

12. The device of claim 11, wherein the cross-section of the one of the semiconductor devices is a cross-section taken perpendicular to a longitudinal direction of a channel of the one of the semiconductor devices.

13. The device of claim 12, wherein the scattering term is calculated based on a square of a correction energy magnitude (Equation 1) calculated by:
$${\vert M \vert}^{2} = \vert < {ψ}_{i , j} {\vert {ψ}_{k , l} > \frac{{ℏ}^{2}}{2 {{m}_{x} ( Δ x )}^{2}} \vert}^{2} \qquad ( Equation 1 )$$
where i and k are indexes of a specific position, j and l are indexes of a subband number, ψ_{i,j} and ψ_{k,l}, are wave functions, mₓ is a mass of a carrier in an x direction, Δx is a distance between xᵢ and xₖ, ℏ is a reduced Planck constant, and |M| is a correction energy magnitude.

14. The device of claim 13, wherein the correction energy magnitude is determined based on the carrier not transitioning from a subband of one number to a subband of another number, when the carrier moves in the longitudinal direction of the channel.

15. The device of claim 13, wherein the correction energy magnitude is determined based on a similarity of zero between subbands of different numbers among the subbands.

16. The device of claim 13, wherein the correction energy magnitude is determined based upon the shape of the cross-section of the one of the semiconductor devices taken in a direction perpendicular to the longitudinal direction of a channel being constant in the longitudinal direction of the channel.

17. The device of claim 13, wherein the scattering term is calculated by:
$$\frac{1}{{τ}_{geo , out}} ( {x}_{i} , m , E ) = \frac{2 π}{ℏ} {\vert M \vert}^{2} Z ( {x}_{i + 1} , n , E ) [ 1 - f ( {x}_{i + 1} , n , E ) ] Δ x \qquad ( Equation 2 )$$
where, xᵢ and xᵢ₊₁ are specific positions, m and n are subband numbers,
$$\frac{1}{{τ}_{geo , out}}$$
is a scattering term, ℏ is the reduced Planck constant, E is a specific energy, Z is a density-of-states, f is a carrier distribution function, Δx is a distance between xᵢ and xᵢ₊₁, and |M|² is a square of the correction energy magnitude.

18. The device of claim 17, wherein the multi-subband Boltzmann transport equation is:
$$v ( {x}_{i + 0.5} , m ) Z ( {x}_{i + 0.5} , m ) f ( {x}_{i + 0.5} , m ) - v ( {x}_{i - 0.5} , m ) Z ( {x}_{i - 0.5} , m ) f ( {x}_{i - 0.5} , m ) - \frac{1}{{τ}_{geo , out}} Z ( {x}_{i} , m ) f ( {x}_{i} , m ) Δ x \qquad ( Equation 3 )$$
where ν is a speed of the carrier in the first direction, x_{i+0.5} and x_{i-0.5} are specific positions, m is the subband number, E is the specific energy, Z is the state density, f is the carrier distribution function, Δx is a distance between x_{i+0.5} and x_{i-0.5}, and
$$\frac{1}{{τ}_{geo , out}}$$
is a scattering term.

19. The device of claim 11, wherein the scattering term is determined based on a ratio in which a carrier belonging to a first subband among the carriers transitions to a second subband of a different number from the first subband number when the carrier moves in a first direction.

20. (canceled)

21. A system comprising:
a semiconductor device;
a measurement device configured to measure characteristics of the semiconductor device; and
a simulation device configured to simulate a performance of a semiconductor device model corresponding to the semiconductor device,
wherein the simulation device is configured to:
calculate a solution of a multi-subband Boltzmann transport equation that includes a scattering term based on code data representing the multi-subband Boltzmann transport equation with scattering terms and characteristics data representing characteristics relating to the semiconductor device model;
generate a performance value of the semiconductor device model corresponding to the solution of the multi-subband Boltzmann transport equation as a result value of a simulation of the simulation device, and
output an evaluation value obtained by evaluating performance of the semiconductor device, based on the result value of the simulation and a measurement value provided by the measurement device,
wherein the scattering term is determined based on geometric scattering of carriers in a region where a shape of a cross-section of the semiconductor device taken in a direction perpendicular to a first direction changes in the first direction.

22.-30. (canceled)
